(19) United States
(12) Patent Application Publication
(10) Pub. No.: US 2017/0263678 A1
(43) Pub. Date: Sep. 14, 2017

(54) MAGNETIC MEMORY DEVICE

(71) Applicant: KABUSHIKI KAISHA TOSHIBA, Tokyo (JP)

(72) Inventor: Eiji KITAGAWA, Kawasaki Kanagawa (JP)

(73) Assignee: KABUSHIKI KAISHA TOSHIBA, Tokyo (JP)

(21) Appl. No.: 15/268,534

(22) Filed: Sep. 16, 2016

Related U.S. Application Data
(60) Provisional application No. 62/306,991, filed on Mar. 11, 2016.

(51) Int. Cl. H01L 27/22; H01L 43/02; H01L 43/10; H01L 43/08

(52) U.S. Cl. CPC H01L 27/228; H01L 43/08; H01L 43/02; H01L 43/10

(57) ABSTRACT

According to one embodiment, a magnetic memory device includes a stacked structure which comprises a first magnetic layer having a variable magnetization direction, a second magnetic layer, and a nonmagnetic layer provided between the first magnetic layer and the second magnetic layer, and is allowed to be selectively set to a low-resistance state and a high-resistance state having a resistance greater than that of the low-resistance state based on a magnetization direction of the first magnetic layer, the high-resistance state being stable in a stationary state where no current flows through the stacked structure, and a magnetic field supply unit which supplies, to the first magnetic layer, a magnetic field having a direction opposite to a direction of a vertical magnetic field component of a total magnetic field applied from the second magnetic layer to the first magnetic layer.

### CROSS-REFERENCE TO RELATED APPLICATIONS

This application claims the benefit of U.S. Provisional Application No. 62/306,991, filed Mar. 11, 2016, the entire contents of which are incorporated herein by reference.

### FIELD

Embodiments described herein relate generally to a magnetic memory device.

### BACKGROUND

A magnetic memory device (semiconductor integrated circuit device) in which a magnetoresistive element and a MOS transistor are integrated on a semiconductor substrate has been suggested.

In the above magnetoresistive element, data is written by supplying a write current to the magnetoresistive element. Data is read by supplying a read current less than the write current to the magnetoresistive element. Thus, writing may be performed erroneously at the time of reading.

To solve the above problem, a magnetic memory device comprising a magnetoresistive element which can prevent erroneous execution of writing at the time of reading is required.

### BRIEF DESCRIPTION OF THE DRAWINGS

FIG. 1 is an explanatory diagram schematically showing the conceptual structure of a magnetic memory device according to a first embodiment.

FIG. 2 schematically shows the overall structure of the magnetic memory device for realizing the structure shown in FIG. 1 according to the first embodiment.

FIG. 3 schematically shows the structures of a magnetoresistive element and a MOS transistor, etc., provided in an integrated circuit chip shown in FIG. 2 according to the first embodiment.

FIG. 4 is a cross-sectional view schematically showing the specific structure of the magnetoresistive element according to the first embodiment.

FIG. 5 is a phase diagram of bias-RH of the magnetoresistive element according to the first embodiment.

FIG. 6 shows the relationship between the temperature of the magnetoresistive element and the change in shift magnetic field according to the first embodiment.

FIG. 7 is a phase diagram of bias-RH of the magnetoresistive element when the temperature of the magnetoresistive element is increased according to the first embodiment.

FIG. 8 is a cross-sectional view schematically showing the specific structure of a magnetoresistive element according to a second embodiment.

FIG. 9 is a cross-sectional view schematically showing the specific structures of a magnetoresistive element and an interconnection according to a third embodiment.

FIG. 10 is a plan view schematically showing the specific structures of the magnetoresistive element and the interconnection according to the third embodiment.

### DETAILED DESCRIPTION

In general, according to one embodiment, a magnetic memory device includes: a stacked structure which comprises a first magnetic layer having a variable magnetization direction, a second magnetic layer, and a nonmagnetic layer provided between the first magnetic layer and the second magnetic layer, and is allowed to be selectively set to a low-resistance state and a high-resistance state having a resistance greater than that of the low-resistance state based on a magnetization direction of the first magnetic layer, the high-resistance state being stable in a stationary state where no current flows through the stacked structure; and a magnetic field supply unit which supplies, to the first magnetic layer, a magnetic field having a direction opposite to a direction of a vertical magnetic field component of a total magnetic field applied from the second magnetic layer to the first magnetic layer.

Embodiments will be described hereinafter with reference to the accompanying drawings.

### Embodiment 1

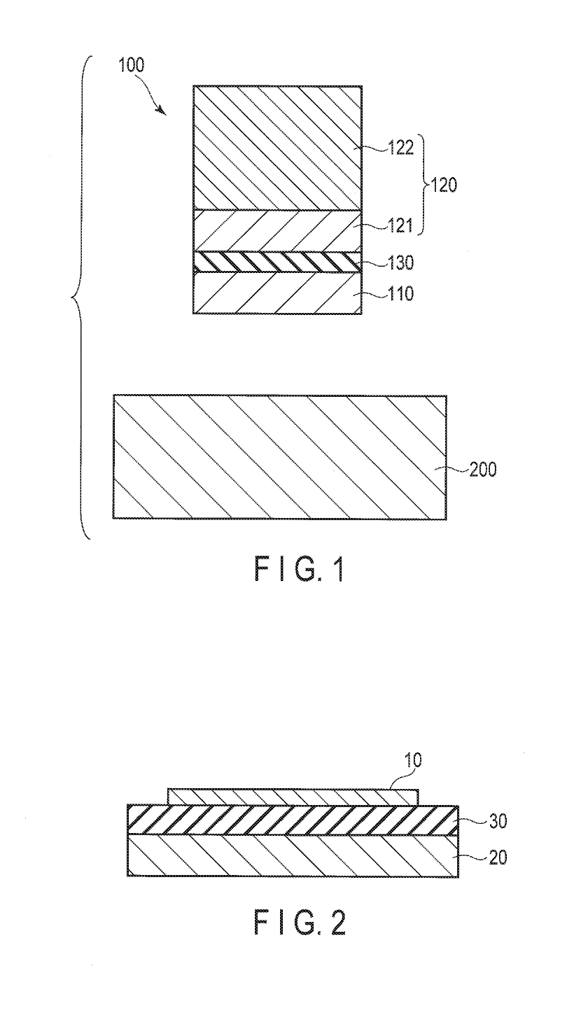

FIG. 1 is an explanatory diagram schematically showing the conceptual structure of a magnetic memory device according to a first embodiment.

As shown in FIG. 1, the magnetic memory device of the present embodiment comprises a stacked structure 100 which functions as a magnetoresistive element, and a magnetic field supply unit 200 which supplies a magnetic field to the stacked structure 100. Specifically, the stacked structure 100 functions as a spin-transfer-torque (STT) magnetoresistive element having a perpendicular magnetization. The magnetoresistive element is also called a magnetic tunnel junction (MTJ) element.

The magnetoresistive element (stacked structure 100) comprises a first magnetic layer 110 having a variable magnetization direction, a second magnetic layer 120, and a nonmagnetic layer 130 provided between the first magnetic layer 110 and the second magnetic layer 120. The first magnetic layer 110 functions as a storage layer in the magnetoresistive element. The second magnetic layer 120 functions as a reference layer and a shift canceling layer in the magnetoresistive element. The nonmagnetic layer 130 functions as a tunnel barrier layer in the magnetoresistive element.

The second magnetic layer 120 includes a first sub-magnetic layer 121 having a fixed first magnetization direction, and a second sub-magnetic layer 122 having a fixed second magnetization direction antiparallel to the first magnetization direction. The first sub-magnetic layer 121 is provided between the nonmagnetic layer 130 and the second sub-magnetic layer 122. As described above, since the magnetization direction of the first sub-magnetic layer 121 is antiparallel to that of the second sub-magnetic layer 122, the direction of magnetic field applied from the first sub-magnetic layer 121 to the first magnetic layer 110 is opposite to that applied from the second sub-magnetic layer 122 to the first magnetic layer 110. The magnetic field applied from the second sub-magnetic layer 122 to the first magnetic layer 110 is greater than that applied from the first sub-magnetic layer 121 to the first magnetic layer 110.

All of the first magnetic layer 110, the first sub-magnetic layer 121 and the second sub-magnetic layer 122 are formed by a ferromagnetic layer having a perpendicular magnetization. The first magnetic layer 110 has a magnetization direction perpendicular to its main surface. The first sub-magnetic layer 121 has a magnetization direction perpendicular to its main surface. The second sub-magnetic layer 122 has a magnetization direction perpendicular to its main surface.

The magnetoresistive element (stacked structure 100) is allowed to be selectively set to a low-resistance state and a high-resistance state having a resistance greater than that of the low-resistance state based on the magnetization direction of the first magnetic layer 110. Specifically, the first magnetic layer 110 is allowed to be selectively set to a first state having a magnetization direction parallel to the first magnetization direction (in other words, to the magnetization direction of the first sub-magnetic layer 121) and a second state having a magnetization direction antiparallel to the first magnetization direction. When the first magnetic layer 110 is in the first state, in other words, when the magnetization direction of the first magnetic layer 110 is parallel to that of the first sub-magnetic layer 121, the magnetoresistive element 100 is set to a low-resistance state. When the first magnetic layer 110 is in the second state, in other words, when the magnetization direction of the first magnetic layer 110 is antiparallel to that of the first sub-magnetic layer 121, the magnetoresistive element 100 is set to a high-resistance state.

Thus, a binary value (0 or 1) can be stored in the magnetoresistive element 100 based on the resistive state (a low- or high-resistance state). The resistive state (a low- or high-resistance state) of the magnetoresistive element 100 can be set based on the direction of the write current flowing through the magnetoresistive element 100. A binary value (a low- or high-resistance state) can be read from the magnetoresistive element 100 by a read current less than the write current.

In the magnetoresistive element (stacked structure 100) of the present embodiment, the high-resistance state is stable in a stationary state. In the magnetoresistive element 100, the high-resistance state is more stable than the low-resistance state in a stationary state where no current (write current or read current) flows through the magnetoresistive element 100. In other words, in the magnetoresistive element 100, a state where the magnetization direction of the first magnetic layer 110 is antiparallel to that of the first sub-magnetic layer 121 is stable in a stationary state. In addition, as described later, in the magnetoresistive element 100, the high-resistance state is more stable than the low-resistance state in a state where a read current flows. Thus, in the magnetoresistive element 100, a transition from a high- to a low-resistance state is more difficult than a transition from a low- to a high-resistance state. In the magnetoresistive element 100, how easily writing can be performed differs depending on the direction of the write current. A state in which the high-resistance state is stable means that the relationship of H1<H2 is satisfied between absolute value H1 of the magnetic switching field in which a low-resistance state is changed to a high-resistance state and absolute value H2 of the magnetic switching field in which a high-resistance state is changed to a low-resistance state in a graph obtained by measuring the magnetic field dependence of the resistance of the magnetoresistive element (stacked structure).

As stated above, in the magnetoresistive element 100, a transition from a high- to a low-resistance state (writing from a high- to a low-resistance state) is difficult. Thus, if the direction of the read current is set the same as that of the write current from a high- to a low-resistance state, it is possible to prevent erroneous execution of writing at the time of reading. In the present embodiment, the direction of the read current which flows through the magnetoresistive element (stacked structure 100) is the same as that of the write current which flows through the magnetoresistive element (stacked structure 100) for setting the magnetoresistive element (stacked structure 100) to a low-resistance state.

If the above structures are simply adopted, it is possible to prevent erroneous execution of writing at the time of reading. However, writing from a high- to a low-resistance state may not be performed. In consideration of this problem, the present embodiment employs a structure which allows a transition from a high- to a low-resistance state to be more easily performed at the time of writing from a high- to a low-resistance state in comparison with at the time of reading. This structure is explained in detail later.

The magnetic field supply unit 200 supplies, to the first magnetic layer 110, a magnetic field having a direction opposite to the direction of the vertical magnetic field component of the total magnetic field applied from the second magnetic layer 120 to the first magnetic layer 110 (in other words, the magnetic field component having a direction perpendicular to the main surface of the first magnetic layer 110). Specifically, a magnetic field having a direction perpendicular to the main surface (the upper or lowers side) of the magnetoresistive element 100 is applied from the magnetic field supply unit 200 to the magnetoresistive element 100. In the example of FIG. 1, the magnetic field supply unit 200 is provided on the first magnetic layer 110 side. However, the magnetic field supply unit 200 may be provided on the second magnetic layer 120 side. This specification further explains the magnetic field supply unit 200.

The magnetic field which is applied from the second sub-magnetic layer 122 to the first magnetic layer 110 includes a magnetic field component having a direction parallel to the main surface of the first magnetic layer 110 (in other words, a horizontal magnetic field component) as well as a magnetic field component having a direction perpendicular to the main surface of the first magnetic layer 110 (in other words, a vertical magnetic field component). As stated above, the direction of the magnetic field applied from the first sub-magnetic layer 121 to the first magnetic layer 110 is opposite to that applied from the second sub-magnetic layer 122 to the first magnetic layer 110. The magnetic field applied from the second sub-magnetic layer 122 to the first magnetic layer 110 is greater than that applied from the first sub-magnetic layer 121 to the first magnetic layer 110. Thus, in the macnetoresistive element 100, a transition from a high- to a low-resistance state (writing from a high- to a low-resistance state) is made difficult by a great horizontal magnetic field component applied from the second sub-magnetic layer 122 to the first magnetic layer 110. In the magnetoresistive element 100 of the present embodiment, the direction of the read current is set the same as that of the write current from a high- to a low-resistance state. This configuration prevents erroneous execution of writing at the time of reading.

However, if the magnetic field applied from the second sub-magnetic layer 122 to the first magnetic layer 110 is great, the vertical magnetic field component applied from the second sub-magnetic layer 122 to the first magnetic layer 110 is also great. Thus, the vertical magnetic field component applied from the second sub-magnetic layer 122 to the first magnetic layer 110 is greater than that applied from the first sub-magnetic layer 121 to the first magnetic layer 110. Thus, the storage holding properties of the magnetoresistive element 100 are detrimentally affected.

In the present embodiment, a vertical magnetic field is supplied from the magnetic field supply unit 200 to the first magnetic layer 110. Therefore, it is possible to cancel the total vertical magnetic field component applied from the second magnetic layer 120 to the first magnetic layer 110. As a result, it is possible to inhibit a detrimental effect to be applied to the storage holding properties of the magnetoresistive element 100.

As described above, in the present embodiment, the magnetic field applied from the second sub-magnetic layer 122 to the first magnetic layer 110 is made great in order to stabilize the high-resistance state of the magnetoresistive element 100. The direction of the read current is set the same as that of the write current from a high- to a low-resistance state. This configuration prevents erroneous execution of writing at the time of reading. Further, a magnetic field having a direction opposite to the direction of the vertical magnetic field component of the magnetic field applied from the second sub-magnetic layer 122 to the first magnetic layer 110 is supplied from the magnetic field supply unit 200 to the first magnetic layer 110. With this configuration, the total vertical magnetic field component applied from the second magnetic layer 120 to the first magnetic layer 110 can be canceled. In this manner, an excellent magnetoresistive element 100 can be obtained.

FIG. 2 schematically shows the overall structure of the magnetic memory device for realizing the structure shown in FIG. 1.

As shown in FIG. 2, an integrated circuit chip (semiconductor integrated circuit chip) 10 is provided above a magnetic field supply unit 20. An insulating material portion 30 is provided between the integrated circuit chip 10 and the magnetic field supply unit 20. The integrated circuit chip 10, the magnetic field supply unit 20 and the insulating material portion 30 are provided in the same package. The position of the magnetic field supply unit 20 is not particularly limited as long as the integrated circuit chip 10 and the magnetic field supply unit 20 are included in the same package, and further, a vertical magnetic field can be applied from the magnetic field supply unit 20 to the macnetoresistive element (MTJ element) of the integrated circuit chip 10.

The integrated circuit chip 10 is a magnetic random access memory (MRAM) chip including the magnetoresistive element (stacked structure 100) shown in FIG. 1 and a MOS transistor, etc. The magnetic field supply unit 20 corresponds to the magnetic field supply unit 200 shown in FIG. 1, and is formed by, for example, a permanent magnet. The magnetic field supply unit 20 is provided away from the magnetoresistive element (stacked structure 100). The magnetic field produced from the magnetic field supply unit 20 is applied to the magnetoresistive element of the integrated circuit chip 10 through the insulating material portion 30.

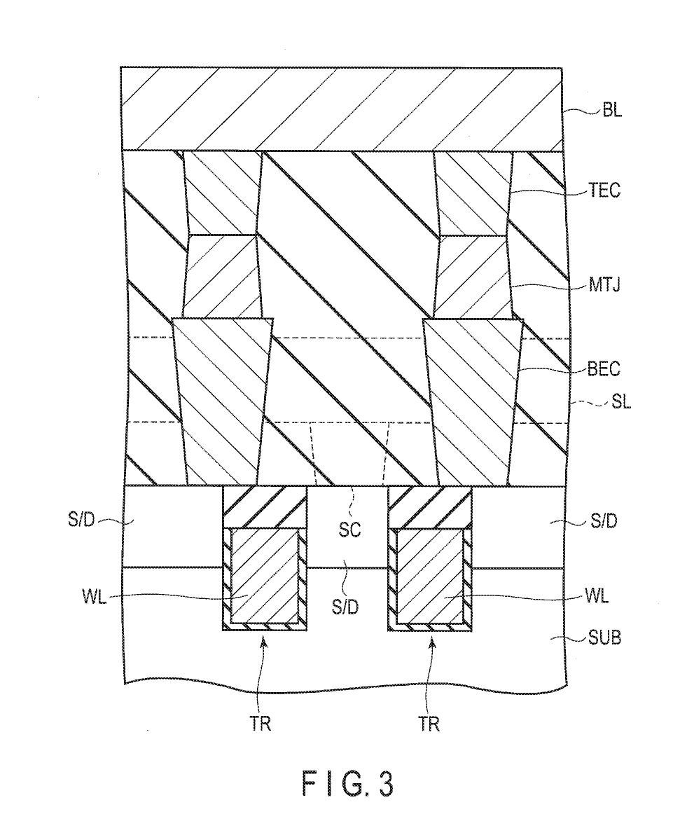

FIG. 3 schematically shows the structures of the magnetoresistive element (MTJ element) and the MOS transistor, etc., provided in the integrated circuit chip 10 shown in FIG. 2.

A buried-gate MOS transistor TR is formed within a semiconductor substrate SUB. The gate electrode of the MOS transistor TR is used as a word line WL. A bottom electrode BEC is connected to one of the source/drain areas S/D of the MOS transistor TR. A source-line contact SC is connected to the other one of the source/drain areas S/D.

A magnetoresistive element MTJ is formed on the bottom electrode BEG. A top electrode TEC is formed on the magnetoresistive element MTJ. A bit line BL is connected to the top electrode TEC. A source line SL is connected to the source-line contact SC.

The structures shown in FIG. 1, FIG. 2 and FIG. 3, and the matters explained in FIG. 1, FIG. 2 and FIG. 3 are applied to the second and third embodiments described later in a similar manner.

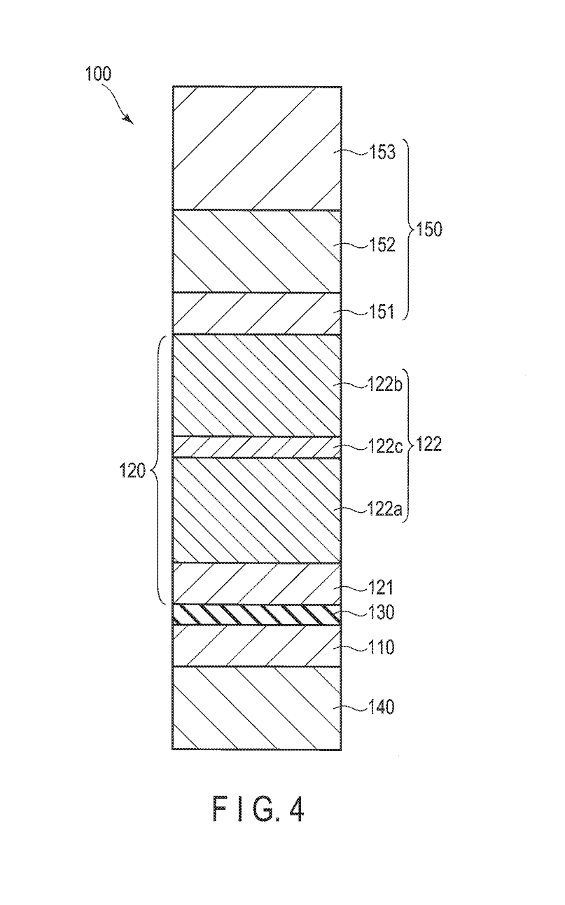

FIG. 4 is a cross-sectional view schematically showing the specific structure of the magnetoresistive element (stacked structure 100) according to the present embodiment. The basic matters are the same as those of the magnetoresistive element (stacked structure 100) explained in FIG. 1. Thus, the explanation of the matters described regarding FIG. 1 is omitted.

As shown in FIG. 4, the magnetoresistive element (stacked structure 100) comprises an underlayer 140, the first magnetic layer 110, the nonmagnetic layer 130, the second magnetic layer 120 and an upper layer 150 in order from the bottom.

The first magnetic layer 110 functions as a storage layer and contains iron (Fe) and boron (B). In addition to iron (Fe) and boron (B), the first magnetic layer 110 may contain cobalt (Co). In the present embodiment, the first magnetic layer 110 comprises CoFeB (cobalt iron boron).

The nonmagnetic layer 130 functions as a tunnel barrier layer and contains magnesium (Mg) and oxygen (O). In the present embodiment, the nonmagnetic layer 130 comprises MgO (magnesium oxide).

As stated above, the second magnetic layer 120 includes the first sub-magnetic layer 121 having the fixed first magnetization direction, and the second sub-magnetic layer 122 having the fixed second magnetization direction antiparallel to the first magnetization direction.

The first sub-magnetic layer 121 functions as at least a part of a reference layer and contains iron (Fe) and boron (B). In addition to iron (Fe) and boron (B), the first sub-magnetic layer 121 may contain cobalt (Co). The magnetization of the first sub-magnetic layer 121 is preferably 1×10⁻⁴ emu/cm² or less such that the magnetic field applied from the second sub-magnetic layer 122 to the first magnetic layer 110 is sufficiently greater than that applied from the first sub-magnetic layer 121 to the first magnetic layer 110. In the present embodiment, the first sub-magnetic layer 121 contains silicon (Si) and tantalum (Ta) to reduce the magnetization, and comprises CoFeBSiTa (cobalt iron boron silicon tantalum).

The second sub-magnetic layer 122 includes a first material layer 122a, a second material layer 122b and an intermediate layer 122c provided between the first material layer 122a and the second material layer 122b. Both the first material layer 122a and the second material layer 122b have the fixed second magnetization direction.

The first material layer 122a contains iron (Fe) and at least one element selected from terbium (Tb), gadolinium (Gd), dysprosium (Dy), rhodium (Rh) and manganese (Mn). Specifically, the first material layer 122a comprises TbCoFe (terbium cobalt iron), GdCoFe (gadolinium cobalt iron), DyCoFe (dysprosium cobalt iron), FeRh (iron rhodium) or FeMn (iron manganese). In the present embodiment, the first material layer 122a comprises TbCoFe containing 35 at % Tb or more. The first material layer 122a functions as a part of a reference layer or a part of a shift canceling layer. Thus, the first material layer 122a may be regarded as a part of a reference layer or a part of a shift canceling layer.

The second material layer 122b contains cobalt (Co) and at least one element selected from platinum (Pt), nickel (Ni), palladium (Pd) and rhodium (Rh). Specifically, the second material layer 122b comprises CoPt (cobalt platinum), CoNi (cobalt nickel), CoPd (cobalt palladium) or CoRh (cobalt rhodium). In the present embodiment, the second material layer 122b comprises CoPt. The second material layer 122b functions as at least a part of a shift canceling layer.

The intermediate layer 122c is formed by a stacked film of ruthenium (Ru) and tantalum (Ta).

The underlayer 140 comprises, for example, HfB (hafnium boron). The upper layer 150 is used as a cap layer, etc., and comprises, for example, a Ta-layer 151, an Ru-layer 152 and a Ta-layer 153.

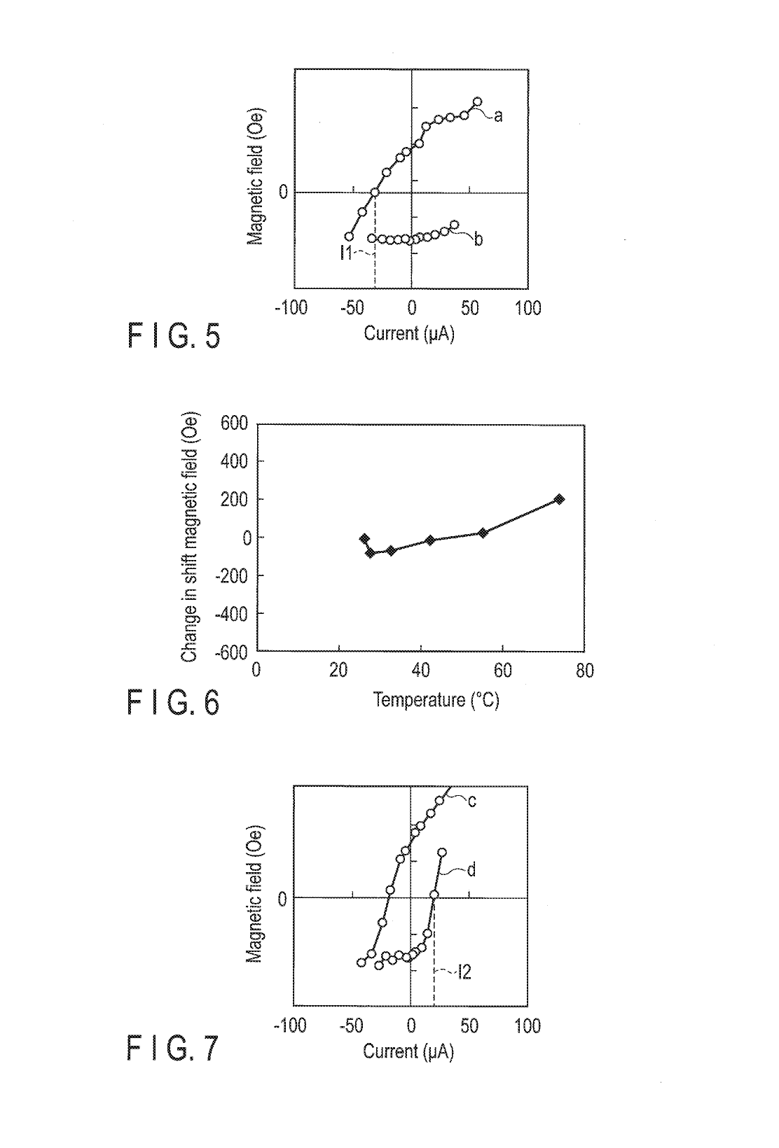

FIG. 5 is a phase diagram of bias-RH of the magnetoresistive element of the present embodiment. The current on the negative side of the horizontal axis indicates the transition of magnetization reversal when current is supplied from the second magnetic layer 120 to the first magnetic layer 110. The current on the positive side of the horizontal axis indicates the transition of magnetization reversal when current is supplied from the first magnetic layer 110 to the second magnetic layer 120.

In characteristic a, the relationship between the magnetization direction of the first magnetic layer 110 and the magnetization direction of the first sub-magnetic layer 121 is changed from a parallel state to an antiparallel state at current I1 in which the curve of characteristic a intersects with the zero line of magnetic field. Thus, writing from a parallel state to an antiparallel state can be performed. In characteristic b, the curve of characteristic b does not intersect with the zero line of magnetic field. Thus, the transition from an antiparallel state to a parallel state is inhibited. In this manner, writing from an antiparallel state to a parallel state cannot be performed. If reading is performed in the direction of the current of this case, it is possible to prevent erroneous execution of writing at the time of reading.

However, writing cannot be performed even at the time of writing in the above state. Thus, it is necessary to generate a state which allows writing at the time of writing. In the present embodiment, a state which allows writing at the time of writing is generated in the following manner.

FIG. 6 shows the relationship between the temperature of the magnetoresistive element and the change in shift magnetic field. FIG. 6 shows that the change in shift magnetic filed increases when the temperature of the magnetoresistive element rises.

FIG. 7 is a phase diagram of bias-RH of the magnetoresistive element when the temperature of the magnetoresistive element is increased to approximately 70° C. As shown in FIG. 7, when the temperature is increased, the curve of characteristic d intersects with the zero line of the magnetic field. Thus, a transition from an antiparallel state to a parallel state (in other words, writing from an antiparallel state to a parallel state) can be realized by increasing the temperature of the magnetoresistive element.

The above state which allows writing from an antiparallel state to a parallel state is generated since the magnetic field applied from the second sub-magnetic layer 122 to the first magnetic layer 110 (in particular, the horizontal magnetic field component) is reduced as the temperature of the second sub-magnetic layer 122 is increased. Specifically, as the temperature of the first magnetic layer 122a included in the second sub-magnetic layer 122 is increased, the magnetization of the first magnetic layer 122a is decreased, and the total magnetization of the second sub-magnetic layer 122 is reduced. As a result, the magnetic field applied from the second sub-magnetic layer 122 to the first magnetic layer 110 (in particular, the horizontal magnetic field component) is decreased. Thus, writing from an antiparallel state (a high-resistance state) to a parallel state (a low-resistance state) can be performed.

The temperature of the second sub-magnetic layer 122 can be increased by supplying a write current to the magnetoresistive element (stacked structure 100). The resistance of the magnetoresistive element (stacked structure 100) in an antiparallel state is greater than that in a parallel state. Thus, when writing from an antiparallel state to a parallel state is performed, the temperature of the magnetoresistive element (stacked structure 100) can be increased by Joule heat. As the read current is less than the write current, an increase in the temperature of the second sub-magnetic layer 122 at the time of reading is small. Thus, a decrease in the magnetization of the second sub-magnetic layer 122 is also small. It is possible to prevent erroneous execution of writing at the time of reading.

As described above, in the present embodiment, the magnetoresistive element is set such that a high-resistance state is stable. The direction of the read current is set the same as that of the write current from a high- to a low-resistance state. This configuration prevents erroneous execution of writing at the time of reading. At the time of writing, the temperature of the second magnetic layer 120 is increased, and the magnetic field applied from the second magnetic layer 120 to the first magnetic layer 110 is decreased. In this manner, writing can be performed. In the present embodiment, it is possible to obtain a magnetic memory device having excellent characteristics such that erroneous execution of writing can be prevented at the time of reading, and further, writing can be performed appropriately at the time of writing.

In the present embodiment, the temperature of the magnetoresistive element 100 is increased by the Joule heat produced in the magnetoresistive element 100, thereby realizing writing from an antiparallel state (a high-resistance state) to a parallel state (a low-resistance state). Thus, a magnetic memory device having excellent characteristics can be obtained without providing a special structure.

### Embodiment 2

Now, this specification explains a magnetic memory device according to a second embodiment. The basic matters are the same as those of the first embodiment. Thus, the explanation of the matters described in the first embodiment is omitted. The matters explained in FIG. 1, FIG. 2, FIG. 3, etc., of the first embodiment are also applied to the present embodiment.

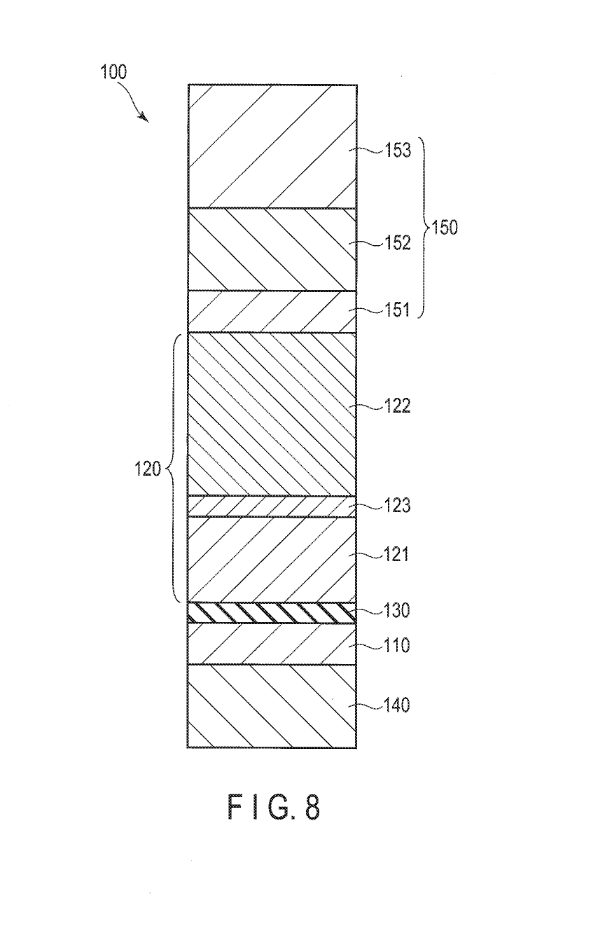

FIG. 8 is a cross-sectional view schematically showing the specific structure of a magnetoresistive element (stacked structure 100) according to the present embodiment.

In a manner similar to that of the first embodiment, the macnetoresistive element (stacked structure 100) comprises an underlayer 140, a first magnetic layer 110, a nonmagnetic layer 130, a second magnetic layer 120 and an upper layer 150 in order from the bottom.

The basic structures and materials of the first magnetic layer 110, the nonmagnetic layer (tunnel barrier layer) 130, the underlayer 140 and the upper layer 150 are the same as those of the first embodiment.

The second magnetic layer 120 includes a first sub-magnetic layer 121 having a fixed first magnetization direction, a second sub-magnetic layer 122 having a fixed second magnetization direction antiparallel to the first magnetization direction, and an intermediate layer 123 provided between the first sub-magnetic layer 121 and the second sub-magnetic layer 122.

The first sub-magnetic layer 121 functions as a reference layer and includes a lower portion and an upper portion provided on the lower portion. The lower portion contains iron (Fe) and boron (B). In addition to iron (Fe) and boron (B), the lower portion may contain cobalt (Co). In the present embodiment, the lower portion comprises CoFeB. The upper portion contains cobalt (Co) and at least one element selected from platinum (Pt), nickel (Ni), palladium (Pd) and rhodium (Rh). Specifically, the upper portion comprises CoPt, CoNi, CoPd or CoRh. In the present embodiment, the upper portion comprises CoPt.

The second sub-magnetic layer 122 functions as a shift canceling layer and includes at least one material layer selected from a first material layer, a second material layer and a third material layer as follows.

The first material layer has an amorphous structure and contains iron (Fe) and at least one of boron (B) and phosphorus (P). Specifically, the first material layer is an amorphous-FeB (iron boron)-layer or an amorphous-FeP (iron phosphorus)-layer. When the first material layer is used for the second sub-magnetic layer 122, another layer may be further provided on the first material layer. In this case, as the second sub-magnetic layer 122, for example, a stacked film of the first material layer (an FeB-layer or an FeP-layer), a Ta-layer and a CoPt-layer can be used in order from the bottom.

The second material layer has an amorphous structure and contains iron (Fe) and at least one rare-earth element. Specifically, an amorphous-DyFe (dysprosium iron)-layer, an amorphous-HoFe (holmium iron)-layer or an amorphous-ErFe (erbium iron)-layer can be used for the second material layer.

The third material layer has a bcc-crystal structure and contains iron (Fe). Specifically, the third material layer is an FeCr (iron chromium)-layer comprising a bcc-crystal structure, an FeMn (iron manganese)-layer comprising a bcc-crystal structure or an FeV (iron vanadium)-layer comprising a bcc-crystal structure. When the third material layer is used for the second sub-magnetic layer 122, another layer may be further provided on the third material layer. In this case, as the second sub-magnetic layer 122, for example, a stacked film of the third material layer (an FeCr-layer, an FeMn-layer or an FeV-layer), a Ta-layer and a CoPt-layer can be used in order from the bottom.

The intermediate layer 123 is formed by a stacked film of ruthenium (Ru) and tantalum (Ta).

In the present embodiment, in a manner similar to that of the first embodiment, writing from an antiparallel state to a parallel state cannot be performed at normal temperature. Thus, in a manner similar to that of the first embodiment, reading is performed in the direction of the current of this case. This configuration prevents erroneous execution of writing at the time of reading.

In the present embodiment, in a manner similar to that of the first embodiment, the temperature of the magnetoresistive element is increased. This configuration enables writing from an antiparallel state to a parallel state. Since the magnetization field applied from the second sub-magnetic layer 122 to the first magnetic layer 110 (in particular, the horizontal magnetic field component) is decreased as the temperature of the second sub-magnetic layer 122 is increased, writing from an antiparallel state to a parallel state can be performed. Specifically, as the temperature of the material layers (the first to third material layers) included in the second sub-magnetic layer 122 is increased, the magnetization of the material layers is decreased, and the total magnetization of the second sub-magnetic layer 122 is reduced. As a result, the magnetic field applied from the second sub-magnetic layer 122 to the first magnetic layer 110 (in particular, the horizontal magnetic field component) is decreased. Thus, writing from an antiparallel state (a high-resistance state) to a parallel state (a low-resistance state) can be performed.

The temperature of the second sub-magnetic layer 122 can be increased by Joule heat by supplying a write current to the magnetoresistive element (stacked structure 100) in a manner similar to that of the first embodiment.

In the present embodiment, in a manner similar to that of the first embodiment, it is possible to obtain a magnetic memory device having excellent characteristics such that erroneous execution of writing can be prevented at the time of reading, and further, writing can be performed appropriately at the time of writing.

### Embodiment 3

Now, this specification explains a magnetic memory device according to a third embodiment. The basic matters are the same as those of the first embodiment. Thus, the explanation of the matters described in the first embodiment is omitted. The matters explained in FIG. 1, FIG. 2, FIG. 3, etc., of the first embodiment are also applied to the present embodiment.

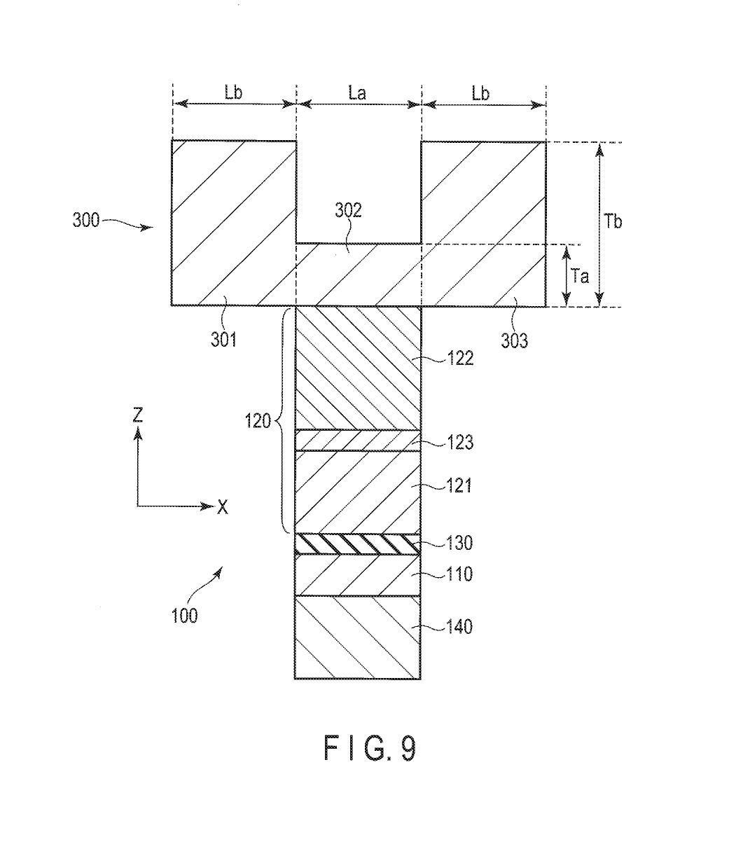

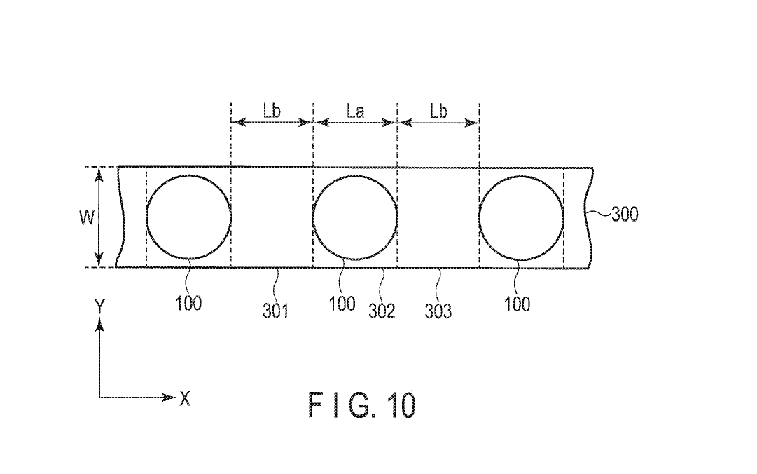

FIG. 9 is a cross-sectional view schematically showing the specific structures of a magnetoresistive element (stacked structure 100) and an interconnection 300 according to the present embodiment. FIG. 10 is a plan view schematically showing the specific structures of the magnetoresistive element (stacked structure 100) and the interconnection 300 according to the present embodiment.

As shown in FIG. 9 and FIG. 10, in addition to the magnetoresistive element (stacked structure 100), the magnetic memory device of the present embodiment comprises the interconnection 300 electrically connected to the magnetoresistive element (stacked structure 100).

The magnetoresistive element (stacked structure 100) comprises an underlayer 140, a first magnetic layer 110, a nonmagnetic layer 130 and a second magnetic layer 120 in order from the bottom.

The basic structures and materials of the first magnetic layer 110, the nonmagnetic layer (tunnel barrier layer) 130 and the underlayer 140 are the same as those of the first embodiment.

The second magnetic layer 120 includes a first sub-magnetic layer 121 having a fixed first magnetization direction, a second sub-magnetic layer 122 having a fixed second magnetization direction antiparallel to the first magnetization direction, and an intermediate layer 123 provided between the first sub-magnetic layer 121 and the second sub-magnetic layer 122.

The first sub-magnetic layer 121 functions as a reference layer and includes a lower portion and an upper portion provided on the lower portion. The lower portion contains iron (Fe) and boron (B). In addition to iron (Fe) and boron (B), the lower portion may contain cobalt (Co). In the present embodiment, the lower portion comprises CoFeB. The upper portion contains cobalt (Co) and at least one element selected from platinum (Pt), nickel (Ni), palladium (Pd) and rhodium (Rh). Specifically, the upper portion comprises CoPt, CoNi, CoPd or CoRh. In the present embodiment, the upper portion comprises CoPt.

The second sub-magnetic layer 122 functions as a shift canceling layer and contains cobalt (Co) and at least one element selected from platinum (Pt), nickel (Ni), palladium (Pd) and rhodium (Rh). Specifically, the second sub-magnetic layer 122 comprises CoPt, CoNi, CoPd or CoRh. In the present embodiment, the second sub-magnetic layer 122 comprises CoPt.

The intermediate layer 123 comprises ruthenium (Ru).

The interconnection 300 functions as a bit line and comprises a magnetic domain-wall structure. Specifically, the interconnection 300 includes a first portion 301, a second portion 302 and a third portion 303 arranged in the extension direction of the interconnection 300 (the X-direction in FIG. 9 and FIG. 10). The second portion 302 is provided at a position corresponding to the position of the pattern of the magnetoresistive element (stacked structure 100). In the present embodiment, the second portion 302 is provided on the magnetoresistive element (stacked structure 100). The first portion 301 is adjacent to one end of the second portion 302. The third portion 303 is adjacent to the other end of the second portion 302.

The length of the first portion 301 (in the X-direction) is equal to that of the third portion 303 (in the X-direction). The thickness of the first portion 301 (in the Z-direction) is equal to that of the third portion 303 (in the Z-direction). All of the width W of the interconnection 300 (in the Y-direction), length Lb of the first portion 301, length La of the second portion 302 and length Lb of the third portion 303 are greater than thickness Ta of the second portion 302, and less than thickness Tb of the first portion 301 and thickness Tb of the third portion 303.

The second portion 302 has a magnetization direction parallel to the extension direction of the interconnection 300 (X-direction) in a stationary state where no current flows through the interconnection 300. In other words, the second portion 302 has a magnetization direction parallel to the extension direction of the interconnection 300 in a stationary state where no current (write current or read current) is supplied to the interconnection 300. The first portion 301 has a fixed magnetization direction parallel to the magnetization direction of the second sub-magnetic layer 122. The third portion 303 has a fixed magnetization direction antiparallel to the magnetization direction of the second sub-magnetic layer 122.

When a write current for the magnetoresistive element (stacked structure 100) is supplied to the interconnection 300, current is supplied from the second portion 302 to the third portion 303, and thus, a spin-torque is applied from the third portion 303 to the second portion 302. In this manner, the magnetization direction of the second portion 302 is set to a magnetization direction antiparallel to the magnetization direction of the second sub-magnetic layer 122. When a read current for the magnetoresistive element (stacked structure 100) is supplied to the interconnection 300, current is supplied from the second portion 302 to the first portion 301, and thus, a spin-torque is applied from the first portion 301 to the second portion 302. In this manner, the magnetization direction of the second portion 302 is set to a magnetization direction parallel to the magnetization direction of the second sub-magnetic layer 122. Alternatively, the magnetization direction of the second portion 302 is set to a magnetization direction parallel to the extension direction of the interconnection 300 (X-direction) by using less current which does not change the magnetization direction of the second portion 302.

A magnetic material having a high magnetic permeability is preferably used for the interconnection 300. Specifically, the material of the interconnection 300 is preferably selected from a magnetic material (permalloy) containing iron (Fe) and nickel (Ni), a magnetic material (sendust) containing iron (Fe), silicon (Si) and aluminum (Al), a magnetic material (ferrite) containing iron (Fe) and oxygen (O), and an amorphous magnetic material.

In the magnetic memory device of the present embodiment, the interconnection 300 comprises a magnetic domain-wall structure. Thus, the magnetization direction of the second portion 302 provided on the magnetoresistive element 100 is set to a magnetization direction antiparallel to the magnetization direction of the second sub-magnetic layer 122 only at the time of writing. Thus, writing can be performed. It is possible to prevent erroneous execution of writing at the time of reading by supplying a read current in the direction of the current supplied at the time of writing from an antiparallel state (a high-resistance state) to a parallel state (a low-resistance state) based on the principle explained in the first and second embodiments.

As described above, in the present embodiment, in a manner similar to that of the first and second embodiments, it is possible to obtain a magnetic memory device having excellent characteristics such that erroneous execution of writing can be prevented at the time of reading, and further, writing can be performed appropriately at the time of writing.

In the first, second and third embodiments, the magnetoresistive element (stacked structure 100) comprises a structure in which the first magnetic layer 110, the nonmagnetic layer 130 and the second magnetic layer 120 are stacked in this order. However, the magnetoresistive element may comprise a structure in which the second magnetic layer 120, the nonmagnetic layer 130 and the first magnetic layer 110 are stacked in this order. For example, in the magnetoresistive element 100 of the first embodiment shown in FIG. 4, layer 122b, layer 122c, layer 122a, layer 121, layer 130 and layer 110 may be stacked in this order. In the magnetoresistive element 100 of the second and third embodiments shown in FIG. 8 and FIG. 9, layer 122, layer 123, layer 121, layer 130 and layer 110 may be stacked in this order. In this case, in the third embodiment, the interconnection 300 is provided under the magnetoresistive element (stacked structure 100).

In the first and second embodiments, the temperature of the second sub-magnetic layer 122 is increased by the heat generation of the magnetoresistive element (stacked structure 100) itself. However, the temperature of the second sub-magnetic layer 122 may be increased by providing a heater element separately from the magnetoresistive element (stacked structure 100).

In the above described first to third embodiments, expressions such as CoFeB, MgO and TbCoFe do not always mean a composition ratio of each of these materials. For example, the expression of CoFeB means that CoFeB material contains Co, Fe and B. It is the same about materials described in the first to third embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic memory device comprising:
a stacked structure which comprises a first magnetic layer having a variable magnetization direction, a second magnetic layer, and a nonmagnetic layer provided between the first magnetic layer and the second magnetic layer, and is allowed to be selectively set to a low-resistance state and a high-resistance state having a resistance greater than that of the low-resistance state based on a magnetization direction of the first magnetic layer, the high-resistance state being stable in a stationary state where no current flows through the stacked structure; and
a magnetic field supply unit which supplies, to the first magnetic layer, a magnetic field having a direction opposite to a direction of a vertical magnetic field component of a total magnetic field applied from the second magnetic layer to the first magnetic layer.

2. The magnetic memory device of claim 1, wherein
a direction of a read current flowing through the stacked structure is the same as that of a write current flowing through the stacked structure for setting the stacked structure to the low-resistance state.

3. The magnetic memory device of claim 1, wherein
the second magnetic layer includes a first sub-magnetic layer having a fixed first magnetization direction, and a second sub-magnetic layer having a fixed second magnetization direction antiparallel to the first magnetization direction, and the first sub-magnetic layer is provided between the nonmagnetic layer and the second sub-magnetic layer, and
a magnetic field applied from the second sub-magnetic layer to the first magnetic layer is greater than a magnetic field applied from the first sub-magnetic layer to the first magnetic layer.

4. The magnetic memory device of claim 3, wherein
the stacked structure is set to the low-resistance state when the magnetization direction of the first magnetic layer is parallel to the magnetization direction of the first sub-magnetic layer, and
the stacked structure is set to the high-resistance state when the magnetization direction of the first magnetic layer is antiparallel to the magnetization direction of the first sub-magnetic layer.

5. The magnetic memory device of claim 3, wherein
the first sub-magnetic layer contains iron (Fe) and boron (B).

6. The magnetic memory device of claim 5, wherein
the first sub-magnetic layer further contains cobalt (Co).

7. The magnetic memory device of claim 3, wherein
the magnetic field applied from the second sub-magnetic layer to the first magnetic layer is decreased as a temperature of the second sub-magnetic layer is increased.

8. The magnetic memory device of claim 7, wherein
the temperature of the second sub-magnetic layer is increased by supplying a write current to the stacked structure.

9. The magnetic memory device of claim 7, wherein
the second sub-magnetic layer includes a first material layer containing iron (Fe) and at least one element selected from terbium (Tb), gadolinium (Gd), dysprosium (Dy), rhodium (Rh) and manganese (Mn).

10. The magnetic memory device of claim 9, wherein
the second sub-magnetic layer further includes a second material layer containing cobalt (Co) and at least one element selected from platinum (Pt), nickel (Ni), palladium (Pd) and rhodium (Rh).

11. The magnetic memory device of claim 7, wherein
the second sub-magnetic layer includes at least one material layer selected from a first material layer, a second material layer and a third material layer,
the first material layer has an amorphous structure and contains iron (Fe) and at least one of boron (B) and phosphorus (P),
the second material layer has an amorphous structure and contains iron (Fe) and at least one rare-earth element, and
the third material layer has a bcc-crystal structure and contains iron (Fe).

12. The magnetic memory device of claim 3, further comprising
an interconnection electrically connected to the stacked structure, wherein
the interconnection includes a first portion, a second portion and a third portion arranged in an extension direction of the interconnection,
the second portion is provided at a position corresponding to a position of a pattern of the stacked structure, and has a magnetization direction parallel to the extension direction of the interconnection in a stationary state where no current flows through the interconnection,
the first portion is adjacent to one end of the second portion, and has a magnetization direction parallel to the magnetization direction of the second sub-magnetic layer, and
the third portion is adjacent to the other end of the second portion, and has a magnetization direction antiparallel to the magnetization direction of the second sub-magnetic layer.

13. The magnetic memory device of claim 12, wherein
all of a width of the interconnection, a length of the first portion, a length of the second portion and a length of the third portion are greater than a thickness of the second portion, and less than a thickness of the first portion and a thickness of the third portion.

14. The magnetic memory device of claim 12, wherein
a magnetization direction of the second portion is set to a magnetization direction antiparallel to the magnetization direction of the second sub-magnetic layer when a write current for the stacked structure is supplied to the interconnection.

15. The magnetic memory device of claim 12, wherein
a magnetization direction of the second portion is set to a magnetization direction parallel to the extension direction of the interconnection or a magnetization direction parallel to the magnetization direction of the second sub-magnetic layer when a read current for the stacked structure is supplied to the interconnection.

16. The magnetic memory device of claim 12, wherein
a material of the interconnection is selected from a magnetic material containing iron (Fe) and nickel (Ni), a magnetic material containing iron (Fe), silicon (Si) and aluminum (Al), a magnetic material containing iron (Fe) and oxygen (O), and an amorphous magnetic material.

17. The magnetic memory device of claim 1, wherein
the first magnetic layer contains iron (Fe) and boron (B).

18. The magnetic memory device of claim 17, wherein
the first magnetic layer further contains cobalt (Co).

19. The magnetic memory device of claim 1, wherein
the nonmagnetic layer contains magnesium (Mg) and oxygen (C).

20. The magnetic memory device of claim 1, wherein
the magnetic field supply unit is provided away from the stacked structure.
